(19) United States
(12) Patent Application Publication
(10) Pub. No.: US 2006/0211170 A1
(43) Pub. Date: Sep. 21, 2006

(54) Semiconductor device and manufacturing method of the same

(75) Inventors: Kiyonori Oyu, Tokyo (JP); Koji Hamada, Tokyo (JP); Yasuhiro Uchiyama, Tokyo (JP); Mitsuo Nissa, Tokyo (JP)

Correspondence Address: SUGHRUE MION, PLLC, 2100 PENNSYLVANIA AVENUE, N.W., SUITE 800, WASHINGTON, DC, 20037, US

(73) Assignee: ELPIDA MEMORY, INC

(21) Appl. No.: 11/376,339

(22) Filed: Mar. 16, 2006

(30) Foreign Application Priority Data
Mar. 17, 2005 (JP) 2005-077977

(51) Int. Cl. H01L 21/00; H01L 23/06

(52) U.S. Cl. 438/106; 257/684

(57) ABSTRACT

A semiconductor device includes an N-type semiconductor region formed in a semiconductor substrate; a p-type semiconductor region formed in a region deeper in the semiconductor substrate than the N-type semiconductor region; and a heavy metal capturing region formed in a portion of the p-type semiconductor region to capture heavy metal ions. The heavy metal capturing region may be a P-type region. It is preferable that the diffusion speed of the heavy metal ions is slower in the heavy metal capturing region than in the p-type semiconductor region.

### BACKGROUND OF THE INVENTION

1. Field of the Invention

The present invention relates to a semiconductor device and a manufacturing method of the same. More particularly, the present invention relates to a technique to reduce affect of heavy metal contamination in a semiconductor device.

2. Description of the Related Art

A depletion layer is formed in a PN junction of a semiconductor device. Crystal defects, heavy metals, and so on, which are present in the depletion layer, provide deep energy levels, which function as recombination centers between electrons and holes. As a result, electric current is generated in the depletion layer, and a junction leakage current flows even by a relatively lower reverse bias voltage which is nearly equal to an operation voltage. Since increase in the junction leakage current causes an erroneous operation of a circuit, removal of contaminants such as heavy metals and so on is indispensable.

In a DRAM (Dynamic Random Access Memory), particularly, data is stored through holding of carriers in a capacitor. Therefore, the increase in the junction leakage current causes leakage of charges from the capacitor, resulting in deterioration in a data holding characteristic of the DRAM. A conventional DRAM is disclosed in Japanese Laid Open Patent Application (JP-P2003-17586A) and Japanese Patent No. 3,212,150.

FIG. 1 is a sectional view showing a structure of a conventional DRAM. In a DRAM 100, two cell transistors sharing a bit line 130 are formed in a single active region. The active region is surrounded by a shallow trench isolation (STI) 110 buried in a semiconductor substrate. Also, a P-type well layer 102 is formed in the substrate, and a P-type channel layer 103 is formed in the P-type well layer 102. A substrate voltage is applied to the P-type well layer 102 at least. The P-type channel layer 103 determines a threshold voltage of the transistor. Additionally, N-type diffusion layers 104 of a low concentration are formed in the vicinity of a substrate surface as source layers and drain layers. A buried layer 109 is formed for field relaxation under the N-type diffusion layer 104, as disclosed in Japanese Patent No. 3,212,150. An N-type buried well layer (not shown) is also formed under the P-type well layer 102.

A gate insulting film 111 is formed on the substrate, and a gate electrode 120 is formed on the gate insulating film 111. The gate electrode 120 includes a polysilicon film into which phosphorus is doped, and a tungsten silicide film. A thermally oxidized film 122 is formed to side surfaces of the gate electrode 120, to improve a breakdown voltage of the gate insulating film. A side spacer 123 is formed in side positions from the gate electrode 120. A silicon nitride film 132 is formed on the gate electrode 120, for gate electrode processing. An interlayer insulating film 133 is formed on the silicon nitride film 132.

A plug 131 is formed to penetrate the gate insulating film 111, the silicon nitride film 132, and the interlayer insulating film 133. One of the plugs 131 connects the bit line 130 and the N-type diffusion layer 104. Other plugs 131 connect other N-type diffusion layers 104 and plugs 143. The plug 143 is connected to a capacitor 150. An interlayer insulating film 141 is formed between the bit line 130 and the plug 143. Further, an interlayer insulating film 142 is formed between the bit line 130 and the capacitor 150.

A semiconductor device having the DRAM 100 as described above, has a peripheral circuit that drives the above cell transistors and performs information processing.

FIG. 2 shows a conventional flow of manufacturing a semiconductor chip of a semiconductor device and packaging the semiconductor chip. FIG. 3 is a cross sectional view of a semiconductor package. In FIG. 3, a BGA (Ball Grid Array) package is shown as an example. The semiconductor chip is assembled into the BGA package as shown in FIG. 3, after undergoing a package assembling process shown in FIG. 2. According to the conventional assembling process, a semiconductor wafer with the semiconductor device formed on a front side is ground on a back side to have a predetermined thickness (steps S101 and S102). Subsequently, dicing is carried out on the semiconductor wafer to obtain semiconductor chips 200 (step S103). Then, the semiconductor chip 200 is attached to a BGA substrate 201 through adhesive (or adhesive tape) 202 (step S104). Subsequently, wire bonding is carried out to connect a wire 203 between an electrode pad of the semiconductor chip 200 and an electrode pad of the BGA substrate 201 (step S105). Then, the semiconductor chip 200 is sealed with a resin 204, and baking is carried out for resin hardening (step S106). Finally, solder balls 205 are attached to the BGA substrate 201 (step S107).

According to the above manufacturing method of the semiconductor device, it is known that heavy metal such as copper and nickel is introduced into the semiconductor water from the back side in steps S101 and S102. FIG. 4 shows one example of distribution of copper and nickel introduced into the semiconductor wafer. In FIG. 4, the vertical axis and horizontal axis show concentration and depth from the back side, respectively. When the semiconductor substrate is a silicon substrate, heavy metals easily diffuse in the semiconductor substrate due to the heat of the baking in the step S106, and reach a wafer surface portion where the DRAM 100 shown in FIG. 1 is formed. For example, it is assumed that the baking for the resin hardening is carried out for several hours at 175° C. At this heat load, diffusion lengths of copper and nickel are approximately 1 mm and 0.1 mm, respectively. Therefore, if the thickness of the semiconductor chip is decreased to 0.2 mm or below, the heavy metals diffuse from the back side to the surface portion where the DRAM 100 is formed.

In the DRAM 100 shown in FIG. 1, a PN junction is formed between the P-type well layer 102 (P-type channel layer 103) and the N-type diffusion layer 104. In this example, from the above reason, there is a possibility that the heavy metal diffuses to a depletion layer between the P-type well layer 102 and the N-type diffusion layer 104. In such a case, the junction leakage current is generated when a reverse bias is applied to the PN junction during an operation of the DRAM 100. In particular, if the junction leakage current is generated in the junction between the P-type well layer 102 and the N-type diffusion layer 104 connected to the capacitor 150, data stored in the capacitor 150 is destructed. Thus, heavy metal contamination is one cause of the deterioration in the data holding characteristic of the DRAM 100.

### SUMMARY OF THE INVENTION

An object of the present invention is to provide a semiconductor device and a manufacturing method of the same, in which heavy metal contamination can be reduced.

Another object of the present invention is to provide a semiconductor device and a manufacturing method of the same, in which a leakage current can be reduced.

Another object of the present invention is to provide a semiconductor device and a manufacturing method of the same, in which a yield can be improved.

Another object of the present invention is to provide a DRAM and a manufacturing method of the same, in which a data holding characteristic can be improved.

In an aspect of the present invention, a semiconductor device includes an N-type semiconductor region formed in a semiconductor substrate; a p-type semiconductor region formed in a region deeper in the semiconductor substrate than the N-type semiconductor region; and a heavy metal capturing region formed in a portion of the p-type semiconductor region to capture heavy metal ions.

Here, the heavy metal capturing region may be a P-type region.

Also, it is preferable that the diffusion speed of the heavy metal ions is slower in the heavy metal capturing region than in the p-type semiconductor region.

Also, it is preferable that an impurity concentration of the heavy metal capturing region is higher than that of the p-type semiconductor region. In this case, the heavy metal capturing region may include a boron layer in which boron is doped, and the concentration of the boron in the boron layer may be equal to or more than 1×10¹⁸ cm⁻³.

Also, the p-type semiconductor region may be a p-type well layer.

Also, the semiconductor device may further include a memory cell having a capacitor connected with the N-type semiconductor region.

In another aspect of the present invention, a method of manufacturing a semiconductor device is achieved by providing a semiconductor chip on which a semiconductor device is formed. Here, the semiconductor device includes: an N-type semiconductor region formed in a semiconductor substrate; and a p-type semiconductor region joined to the N-type semiconductor region. The method of manufacturing a semiconductor device is achieved by further packaging the chip in a package; and applying a reverse bias which is higher than a voltage in a normal operation of the semiconductor device between the N-type semiconductor region and the p-type semiconductor region, after the packing.

Also, in another aspect of the present invention, a method of manufacturing a semiconductor device is achieved by providing a semiconductor chip on which a semiconductor device is formed; by packaging the chip in a package; and by applying a reverse bias which is higher than a voltage in a normal operation of the semiconductor device between an N-type semiconductor region and a p-type semiconductor region, after the packing. Here, the semiconductor device includes the N-type semiconductor region formed in a semiconductor substrate; the p-type semiconductor region formed in a region deeper from a surface of the semiconductor substrate than the N-type semiconductor region; and a heavy metal capturing region formed in a portion of the p-type semiconductor region to capture heavy metal ions.

Here, the heavy metal capturing region includes a boron layer in which boron is doped, and a concentration of the boron in the boron layer is higher than that of the p-type semiconductor region.

In this case, it is preferable that the concentration of the boron in the boron layer is equal to or more than 1×10¹⁸ cm⁻³.

### BRIEF DESCRIPTION OF THE DRAWINGS

FIG. 1 is a sectional view showing a structure of a conventional DRAM;

FIG. 2 is a flow chart showing a conventional package assembling process;

FIG. 3 is a cross sectional view of a semiconductor package;

FIG. 4 is a graph showing a distribution of heavy metals in a conventional DRAM;

FIG. 5 is a sectional view showing a structure of a semiconductor device of the present invention;

FIG. 6 is a flow chart showing a package assembling process of the present invention;

FIGS. 7A and 7B are band diagrams for describing movement of an heavy meal ion in the second embodiment of the present invention;

FIG. 8 is a band diagram for describing effects of the semiconductor device according to the third embodiment of the present invention; and

FIG. 9 describes the effects of the present invention.

### DESCRIPTION OF THE PREFERRED EMBODIMENTS

Hereinafter, a semiconductor device and a manufacturing method of the same of the present invention will be described with reference to the attached drawings.

### First Embodiment

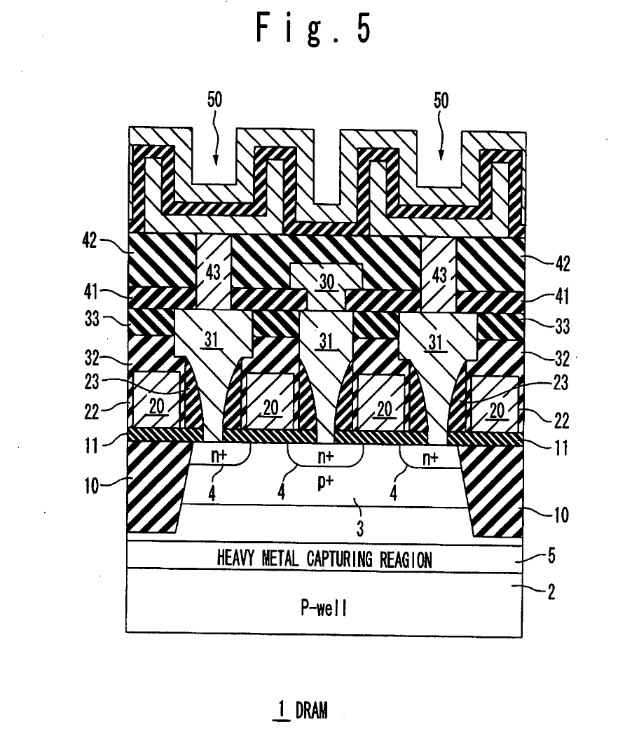

FIG. 5 is a sectional view showing a structure of the semiconductor device according to the first embodiment of the present invention. The semiconductor device in the first embodiment has a DRAM 1 formed on a semiconductor substrate (silicon substrate). In the DRAM 1, two cell transistors are formed in a single active region and share a bit line 30. The active region is surrounded by a shallow trench isolation (STI) 10 buried into the semiconductor substrate. A P-type well layer 2 is formed in the substrate, and a P-type channel doped layer 3 is formed in the P-type well layer 2. A substrate voltage is applied to the P-type well layer 2 at least. The P-type channel doped layer 3 determines a threshold voltage of the transistors. In addition, N-type diffusion layers 4 of low concentration are formed in the vicinity of the substrate surface as a source region and a drain region. That is to say, the P-type well layer 2 (P-type channel doped layer 3) is formed in a deeper position than the N-type diffusion layer 4 from the surface of the semiconductor substrate. An N-type buried well layer (not shown) is formed under the P-type well layer 2.

A gate insulating film 11 is formed on the substrate, and a gate electrode 20 is formed on the gate insulating film 11. The gate electrode 20 includes a polysilicon film into which phosphorus is implanted, and a tungsten silicide film. A thermally oxidized film 22 is formed to side surfaces of the gate electrode 20 to improve a breakdown voltage of the gate insulating film. Side spacers 23 are formed in side positions from the gate electrode 20. In addition, a silicon nitride film 32 is formed on the gate electrode 20 for gate electrode processing. An interlayer insulating film 33 is formed on the silicon nitride film 32.

A plug 31 is formed to penetrate the gate insulating film 11, the silicon nitride film 32, and the interlayer insulating film 33. One of the plugs 31 connects the bit line 30 and the N-type diffusion layer 4. Other plugs 31 connect other N-type diffusion layers 4 and plugs 43. The plug 43 is connected to a capacitor 50. Also, an interlayer insulating film 41 is formed between the bit line 30 and the plug 43. Further, an interlayer insulating film 42 is formed between the bit line 30 and the capacitor 50.

According to the present invention, as shown in FIG. 5, a heavy metal trapping region 5 is formed in a part of the P-type well layer 2. Since the P-type well layer 2 is formed in a deeper position than the N-type diffusion layer 4 from the substrate surface, the heavy metal trapping region 5 is also formed in a deeper position than the N-type diffusion layer 4 from the substrate surface. In addition, as shown in FIG. 5, the heavy metal trapping region 5 may be formed in a deeper position than the STI 10 from the substrate surface.

The heavy metal trapping region 5 has a boron layer into which boron is doped, for example. The boron layer of a high concentration is formed such that the concentration of boron in the boron layer is higher than that of the P-type well layer 2. For example, the concentration of boron in the boron layer is 1×10¹⁸ cm⁻³ or above. For example, the concentration of boron is 3×10¹⁸ cm⁻³. As a result, a diffusion speed of the heavy metal is slower in the heavy metal trapping region 5 than in the P-type well layer 2.

In FIG. 5, an NMOS transistor is exemplified. Alternatively, a PMOS transistor may be used. In that case, an N-type well layer is formed in the substrate, and a P-type diffusion layers as a source layer and a drain layer are formed on the N-type well layer. Also, a P-type buried well layer is formed under the N-type well layer. In this case, the heavy metal capture region 5 may be formed in the P-type buried well layer. That is, according to the present invention, an N-type semiconductor region (N-type diffusion layer 4; N-type well) and a P-type semiconductor region (P-type well layer 2 and 3; P-type buried well layer) are formed in the substrate. The P-type semiconductor region is located deeper than the N-type semiconductor region from the surface of the semiconductor substrate. The heavy metal trapping region 5 is provided in a part of the P-type semiconductor region. Part of or whole region of the heavy metal trapping region 5 is a boron high-concentration layer in which the boron concentration is 1×10¹⁸ cm⁻³ or above.

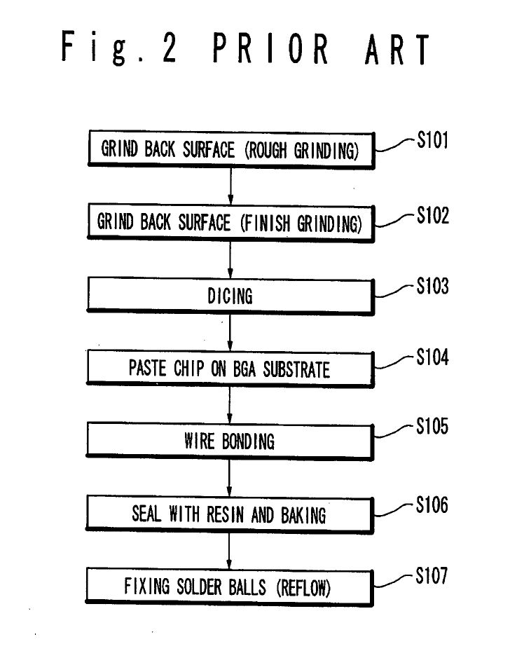

Because of the high-concentration boron layer, the diffusion speed of the heavy metal in the heavy metal trapping region 5 is slower than that in the periphery of the heavy metal trapping region 5. Therefore, even if the assembling process shown in FIG. 2 is carried out, the heavy metal is less likely to reach element portions from the back side of the semiconductor wafer. Even when the heavy metals as copper and nickel diffuse to the surface from the back side of the semiconductor wafer due to the heat of the baking, the heavy metals are trapped in the heavy metal trapping region 5 of the present invention. Therefore, heavy metals that reach a depletion layer between the P-type well layer 2 (P-type channel doped layer 3) and the N-type diffusion layer 4 are decreased. Thus, according to the present invention, effects of heavy metal contamination can be reduced. Therefore, generation of the junction leakage current in the depletion layer is suppressed. Since the junction leakage current is reduced, the data holding characteristic is improved in the DRAM in particular.

### Second Embodiment

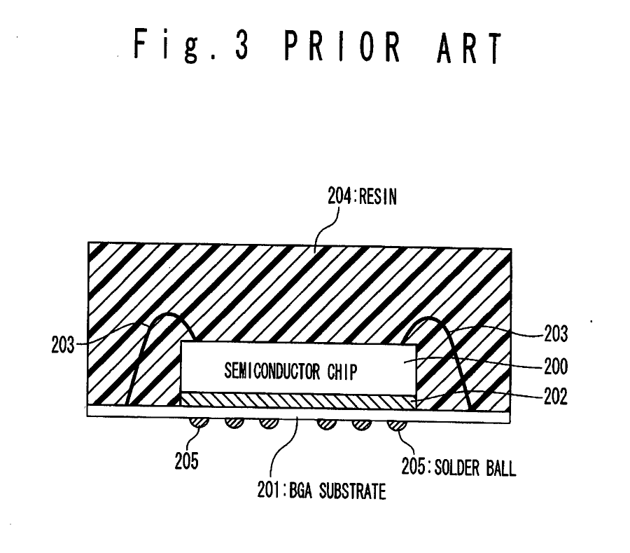

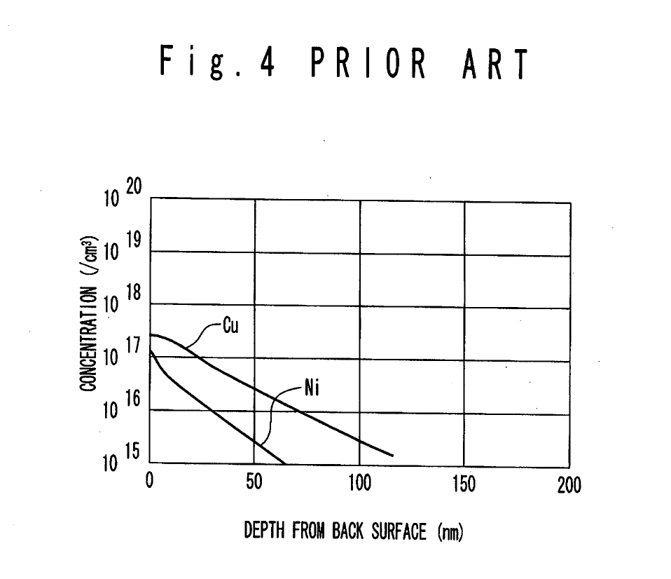

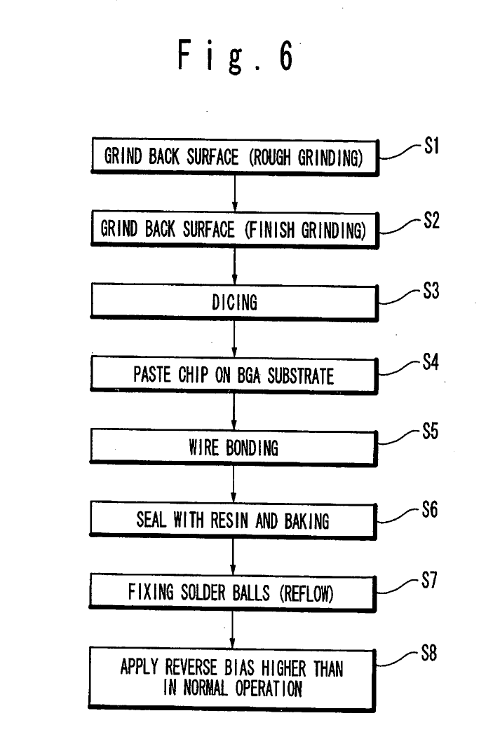

FIG. 6 is a flow chart showing a package assembling process of the present invention. In the package assembling process, a semiconductor chip of a semiconductor device is provided, and the semiconductor chip is packaged. For example, the BGA (Ball Grid Array) package shown in FIG. 3 is manufactured.

First, the semiconductor wafer on whose front surface the semiconductor device is formed is ground on a back side (to which the semiconductor device is not formed) to have a predetermined thickness (steps S1 and S2). Subsequently, dicing is carried out to the semiconductor wafer, obtaining semiconductor chips 200 (step S3). The semiconductor chip 200 is attached to a BGA substrate 201 through adhesive or adhesive tape 202 (step S4). Subsequently, wire bonding is carried out, and a wire 203 is connected between an electrode pad of the semiconductor chip 200 and an electrode pad of the BGA substrate 201 (step S5). Then, the semiconductor chip 200 is sealed with a resin 204, and baking is carried out for resin hardening (step S6). After that, solder balls 205 are attached to the BGA substrate 201 (step S7).

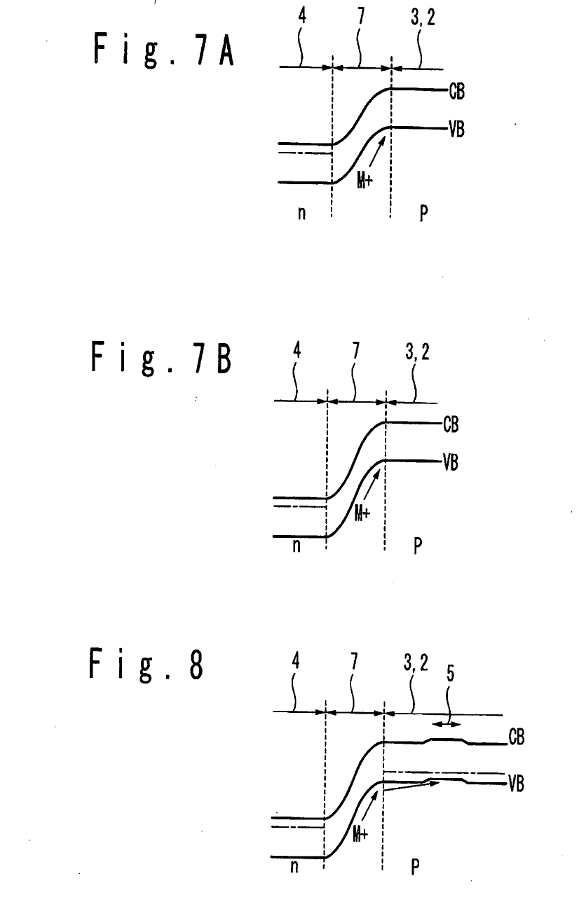

Further, according to the present invention, a reverse bias higher than that in a normal operation is applied between the P-type well layer 2 (P-type channel doped layer 3) and the N-type diffusion layer 4, after the package assembling (step S8). FIGS. 7A and 7B are band diagrams for showing effects of the above step S8. A heavy metal ion that is positively ionized is shown as M+. The heavy metal is introduced in the above steps S1 and S2, diffuses to the depletion layer 7 between the P-type well layer 2 (P-type channel doped layer 3) and the N-type diffusion layer 4, due to the heat load of the baking in step S6. At this time, as shown in FIG. 7A, the positively ionized heavy metal M+ is attracted toward the P-type well layer 2. Also, if the reverse bias is applied in the above step S8, the band has a sharp curve as shown in FIG. 7B. As a result, movement of the heavy metal ion M+ is stimulated and accelerated.

In this way, it is possible to effectively remove heavy metal reaching the depletion layer 7, by applying the reverse bias higher than that in the normal operation, between the P-type well layer 2 (P-type channel doped layer 3) and the N-type diffusion layer 4. Therefore, according to the manufacturing method of the semiconductor device of the present invention, the effects of the heavy metal contamination can be reduced. Thus, generation of the junction leakage current in the depletion layer 7 is restrained. Because of the reduction in the junction leakage current, the data holding characteristic is improved in the DRAM in particular.

### Third Embodiment

It is more effective to perform the package assembling process (see FIG. 6) shown in the second embodiment, after the semiconductor device shown in the first embodiment (see FIG. 5) is provided. That is, the heavy metal trapping region 5 is formed in the P-type well layer 2 of the semiconductor device. Additionally, after the package assembling, the reverse bias higher than that in the normal operation is applied (step S8) between the P-type well layer 2 (P-channel doped layer 3) and the N-type diffusion layer 4. In this case, the heavy metal introduced in the steps S1 and S2 shown in FIG. 6 diffuses toward the surface from the back side of the semiconductor wafer, due to the heat load of the baking in the step S6. In this case, since the heavy metal trapping region 5 is formed, the heavy metal that reaches the depletion layer 7 between the P-type well layer 2 (P-type channel doped layer 3) and the N-type diffusion layer 4, is decreased.

FIG. 8 shows a band diagram similar to FIGS. 7A and 7B. In FIG. 8, a heavy metal ion that is positively ionized is shown as M+. Even if heavy metal passes through the heavy metal trapping region 5 to reach the depletion layer 7, the positively ionized heavy metal M+ is attracted toward the P-type well layer 2 as shown in FIG. 8. If the reverse bias is applied in the step S8, the band has a sharp curve, and movement of the heavy metal ion M+ is stimulated and accelerated. Further, when the boron concentration in the heavy metal trapping region 5 is 1×10¹⁸ cm⁻³ or above, the heavy metal is trapped in the high-concentration boron layer.

In this way, according to the semiconductor device and the manufacturing method of the same of the present invention, the effects of the heavy metal contamination can be reduced. Even if heavy metal reaches the depletion layer 7, the heavy metal can be effectively removed from the depletion layer 7. Therefore, generation of the junction leakage current in the depletion layer 7 is further suppressed. Because of the reduction in the junction leakage current, the data holding characteristic can be improved in the DRAM in particular.

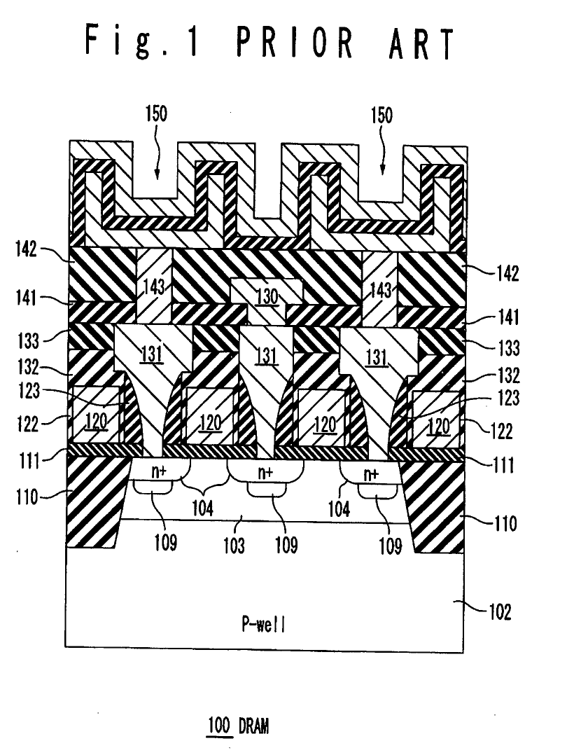

Results of experiments carried out by the inventor of the present invention are shown below, to numerically show the effects of the present invention. Two kinds of DRAMs were used as semiconductor devices, which were the conventional DRAM 100 shown in FIG. 1 and the DRAM 1 of the present invention shown in FIG. 5. Also, two kinds of methods were used as package assembling methods, which were the conventional method shown in FIG. 2 and the method of the present invention shown in FIG. 6. By combining the above semiconductor devices and package assembling methods, four kinds of packages were manufactured. The BGA package shown in FIG. 3 was used as a package.

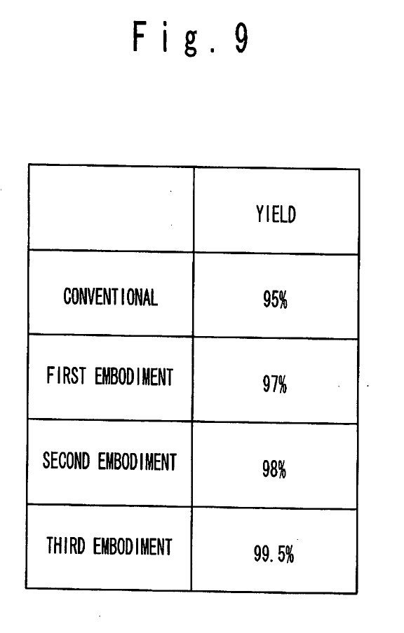

FIG. 9 shows a selection yield for each of the four kinds of packages. In a selecting process, the data holding characteristic is evaluated in a state in which an operating voltage (1.8 V) is applied to the N-type diffusion layer 4 and an operating voltage (−0.5 V) is applied to the P-type channel doped layer 3 and the P-type well layer 2.

First, in case of a conventional example, namely, when the DRAM 100 shown in FIG. 1 and the method shown in FIG. 2 are used, the selection yield satisfying a given data holding characteristic is 95%.

Next, in case of the first embodiment, namely, when the DRAM 1 shown in FIG. 5 and the method shown in FIG. 2 are used, the selection yield satisfying the given data holding characteristic is 97%. The selection yield is improved compared with the conventional example. The improvement of the yield is because the heavy metal trapping region 5 provided below the STI reduces the effects of the heavy metal contamination in the package assembling.

Next, in case of the second embodiment, namely, when the DRAM 100 shown in FIG. 1 and the method shown in FIG. 6 are used, the selection yield satisfying the given data holding characteristic is 98%. Here, in the above step S8 prior to the selecting process, a reverse bias, that is, a voltage (3 V) larger than the operation voltage (1.8 V) applied to the N-type diffusion layer 4, and a voltage (−1.5 V) larger than the operation voltage (−0.5 V) applied to the P-channel doped layer 3 and the P-type well layer 2 is applied for two hours. Thus, the selection yield is improved compared with the conventional example, by providing the process to apply the reverse bias higher than that in the normal operation. The improvement of the yield is because the band has a sharper curve, and heavy metal reaching the depletion layer 7 is attracted toward the P-type well layer 2.

Next, in case of the third embodiment, namely, when the DRAM 1 shown in FIG. 5 and the method shown in FIG. 6 are used, the selection yield satisfying the given data holding characteristic is improved up to 99.5%. Thus, it is possible to greatly improve the selection yield by combining the semiconductor device and the manufacturing method of the same of the present invention. The improvement of the yield is because heavy metal reaching the depletion layer 7 is effectively removed in the heavy metal trapping region 5, and the heavy metal reaching the depletion layer 7 is attracted toward the P-type well layer 2.

As described above, according to the semiconductor device and the manufacturing method of the same of the present invention, the effects of the heavy metal contamination can be reduced. Therefore, the leakage current can be reduced. In addition, the yield is improved, reducing costs. Further, according to the DRAM and the manufacturing method of the same of the present invention, the data holding characteristic is improved. Because of the improvement in the data holding characteristic, power consumption is reduced.

As described above, according to a semiconductor device and a manufacturing method of the same of the present invention, effects of heavy metal contamination can be reduced, and a leakage current can be reduced. As a result, a production yield can be improved, and a data holding characteristic can be improved.

What is claimed is:

1. A semiconductor device comprising:
an N-type semiconductor region formed in a semiconductor substrate;
a p-type semiconductor region formed in a region deeper in said semiconductor substrate than said N-type semiconductor region; and
a heavy metal capturing region formed in a portion of said p-type semiconductor region to capture heavy metal ions.

2. The semiconductor device according to claim 1, wherein said heavy metal capturing region is a P-type region.

3. The semiconductor device according to claim 1, wherein a diffusion speed of said heavy metal ions is slower in said heavy metal capturing region than in said p-type semiconductor region.

4. The semiconductor device according to claim 2, wherein an impurity concentration of said heavy metal capturing region is higher than that of said p-type semiconductor region.

5. The semiconductor device according to claim 4, wherein said heavy metal capturing region comprises a boron layer in which boron is doped, and the concentration of said boron in said boron layer is equal to or more than 1×10¹⁸ cm⁻³.

6. The semiconductor device according to claim 1, wherein said p-type semiconductor region is a p-type well layer.

7. The semiconductor device according to claim 1, further comprising:
a memory cell having a capacitor connected with said N-type semiconductor region.

8. A method of manufacturing a semiconductor device, comprising:
providing a semiconductor chip on which a semiconductor device is formed;
wherein said semiconductor device comprises: an N-type semiconductor region formed in a semiconductor substrate; and a p-type semiconductor region joined to said N-type semiconductor region;
packaging said chip in a package; and
applying a reverse bias which is higher than a voltage in a normal operation of said semiconductor device between said N-type semiconductor region and said p-type semiconductor region, after said packing.

9. A method of manufacturing a semiconductor device, comprising:
providing a semiconductor chip on which a semiconductor device is formed;
wherein said semiconductor device comprises: an N-type semiconductor region formed in a semiconductor substrate; a p-type semiconductor region formed in a region deeper from a surface of said semiconductor substrate than said N-type semiconductor region; and a heavy metal capturing region formed in a portion of said p-type semiconductor region to capture heavy metal ions.
packaging said chip in a package; and
applying a reverse bias which is higher than a voltage in a normal operation of said semiconductor device between said N-type semiconductor region and said p-type semiconductor region, after said packing.

10. The method according to claim 9, wherein said heavy metal capturing region comprises a boron layer in which boron is doped, and
a concentration of said boron in said boron layer is higher than that of said p-type semiconductor region.

11. The method according to claim 10, wherein the concentration of said boron in said boron layer is equal to or more than 1×10¹⁸ cm⁻³.
